(19) United States
(12) Patent Application Publication
(10) Pub. No.: US 2024/0394430 A1
(43) Pub. Date: Nov. 28, 2024

(54) METHOD, APPARATUS AND STORAGE MEDIUM FOR MEASURING THE QUALITY OF BUILT ENVIRONMENT

(71) Applicant: SOUTHEAST UNIVERSITY, Jiangsu (CN)

(72) Inventors: Xiao HAN, Jiangsu (CN); Zhe LI, Jiangsu (CN); Liya WANG, Jiangsu (CN); Jie LI, Jiangsu (CN); Qixin ZHANG, Jiangsu (CN); Mingjing DONG, Jiangsu (CN); Shuang WU, Jiangsu (CN); Mingchen XU, Jiangsu (CN); Haini CHEN, Jiangsu (CN); Yi SHI, Jiangsu (CN); Qiaochu WANG, Jiangsu (CN); Mengyao YU, Jiangsu (CN)

(73) Assignee: SOUTHEAST UNIVERSITY, Jiangsu (CN)

(21) Appl. No.: 18/265,260

(22) PCT Filed: Dec. 8, 2022
(86) PCT No.: PCT/CN2022/137406

§ 371 Date: Jun. 5, 2023

(30) Foreign Application Priority Data
Jun. 8, 2022 (CN) 202210645730.1

(51) Int. Cl. G06F 30/20; G06F 17/16; G06V 20/10

(52) U.S. Cl. CPC G06F 30/20; G06F 17/16; G06V 20/176

(57) ABSTRACT

Disclosed are a method, an apparatus and a storage medium for measuring the quality of a built environment. The method includes the following steps: identifying key influencing factors determining environmental quality, and establishing an index system of environmental quality influencing factors, wherein the key influencing factors include non-observation elements and observation elements; analyzing the relationship between the environmental quality and the key influencing factors to form a theoretical model; acquiring observation elements to form a large sample database; calculating path coefficients of each key influencing factor of environmental quality according to the distribution of sample data in the large sample database, and converting the path coefficients into weights; dividing distribution intervals of all observation elements dynamically according to the distribution of sample data, and defining quality assignments of all observation elements; and performing an environmental quality measurement of samples in combination with the weights and the quality assignments.

### BACKGROUND

### Technical Field

The present disclosure relates to the technical field of quality assessment, and particularly relates to a method, an apparatus and a storage medium for measuring the quality of a built environment.

### Description of Related Art

At present, common quality assessment methods for a built environment are to: construct a multi-dimensional environmental quality assessment system and assessment index elements for a certain type of built environment, determine a grading of each index element according to construction needs of an assessment object, give quality assessment results of sub-elements, and judge whether design objectives can be achieved, so as to bring forward a targeted design optimization strategy (CN202010998144.6, under examination; CN201910407314.6, under examination). In the process of selecting the assessment system and index elements, such type of assessment methods are mostly selected independently based on relevant research literature, and the rationality and systematicness of the assessment system construction need to be verified; in the assessment process of each index element, non-quantifiable index elements are mostly assessed in the scoring form of expert assessment or questionnaire survey, while the assessment grading of non-quantifiable measuring index elements is determined based on past research experience, without considering the distribution of data, and a static parameter interval division of data of each element may cause data to be excessively concentrated in one or several intervals in an unreasonable way, and the purpose of accurate and effective interval assignment cannot be achieved. In the analysis and practical application of the assessment results, most of the research cases focus on assessing the sub-elements, and comparison among the sub-elements before and after reconstruction or the same of multiple design schemes is made, but a simple comparative analysis fails to take into account the complex interaction between these sub-elements, and it is impossible to identify the degree of which elements to be optimized in the built environment, therefore, the assessment results are unreasonable. In the actual construction process, the practicability and reference value of existing technologies have certain limitations, and the efficiency and accuracy of the quality measurement results in practical application need to be improved. Currently, there are few studies on comprehensive measurement of the environmental quality, and there is a lack of a practical and scientific assessment method to assess the environmental quality in complex environment. Therefore, the present disclosure provides a method, an apparatus and a storage medium for measuring the quality of a built environment.

### SUMMARY

In order to overcome the above defects in the background art, an objective of the present disclosure is to provide a method for measuring the quality of a built environment, which is used for solving technical problems that it is difficult for the prior art to achieve scientific measurement and accurate analysis of components and comprehensive quality of the built environment.

The objective of the present disclosure can be realized by the following technical solution: a method for measuring the quality of a built environment, including the following steps:
identifying key influencing factors determining environmental quality, and establishing an index system of environmental quality influencing factors, where the key influencing factors include non-observation elements and observation elements;
analyzing the relationship between the environmental quality and the key influencing factors to form a theoretical model;
acquiring observation elements to form a large sample database;
calculating path coefficients of each key influencing factor of environmental quality according to the distribution of sample data in the large sample database, and converting the path coefficients into weights;
dividing distribution intervals of all observation elements dynamically according to the distribution of sample data, and defining quality assignments of all observation elements; and
performing a comprehensive quality measurement of samples in combination with the weights and the quality assignments

Further, regression equations among latent variables, as well as between latent variables and observation variables are established according to the theoretical model:

assuming that there are m types of non-observation elements and i types of observation elements among the key influencing factors of environmental quality, where the observation elements are the elements that can be measured directly in the built environment, and the corresponding data set is the observation variables; non-observation elements are the factors that cannot be measured directly in the built environment, which need to be reflected indirectly by actual index values, that is, latent variables, acquired through observation. Therefore, a matrix equation between the latent variables and the observation variables is:

$$Y = {Λ}_{y} η + ε$$

A matrix equation among the latent variables is:

$$η = B η + Γ ξ + ζ$$

In the equation:
Y is an i×1-dimensional vector composed of i observation variables yᵢ;
η is an m×1-dimensional vector composed of m latent variables;
Λ_{y} is an i×m-dimensional loading matrix of Y on η, reflecting the relationship between the observation variables Y and the latent variables η;
ε is an i×1-dimensional vector composed of i measurement errors, and is an error item of the observation variables Y;
ξ is a 1×1-dimensional vector composed of 1 exogenous latent variable;
B is an m×m-dimensional coefficient matrix, which represents the interrelationship among endogenous latent variables η, and when there is an interrelationship, the dimension influence coefficient will be recorded as β;
Γ is an m×1-dimensional coefficient matrix composed of m influence coefficients γₘ, which represents the influence of exogenous latent variables ξ on the endogenous latent variables η; and
ξ is an m×1-dimensional vector composed of m interpretation errors, and is an error item of the latent variables η.

Further, an establishment process of the large sample database is as follows:
selecting samples based on the clarity, completeness and availability of vector data of built environment entities and the accuracy of data capable of meeting the requirements for subsequent data analysis to form a large sample case base;
collecting geographical surveying maps and satellite images of the area where the samples are located, and acquiring environmental vector data of the observation elements in combination with the features of the built environment; and
standardizing the original data set and giving reverse assignment of negative correlated elements

$$Positive indicators : {y}_{ij} = \frac{{y}_{ij} - min {\{}_{} {y}_{i 1} , {y}_{i 2} , … {y}_{in} \}}{max {\{}_{} {y}_{i 1} , {y}_{i 2} , … {y}_{in} \} - min {\{}_{} {y}_{i 1} , {y}_{i 2} , … {y}_{in} \}}$$

$$Negative indicators : {y}_{ij} = \frac{max {\{}_{} {y}_{i 1} , {y}_{i 2} , … {y}_{in} \} - {y}_{ij}}{max {\{}_{} {y}_{i 1} , {y}_{i 2} , … {y}_{in} \} - min {\{}_{} {y}_{i 1} , {y}_{i 2} , … {y}_{in} \}}$$

in the equation, yᵢ is the i^{th} endogenous observation variable, yᵢⱼ is the j^{th} sample data in the sample data set of the observation variable yᵢ, {yᵢ, yᵢ₂, . . . yᵢₙ} is the sample data set of the observation variable yᵢ, and n is the number of samples.

Further, a normality test on index vectors is performed, and a skewness coefficient (SK) and a kurtosis coefficient (K) of each index vector is calculated:

$$SK = \frac{n}{( n - 1 ) ( n - 2 )} \sum {( \frac{{y}_{ij} - \overline{{y}_{i}}}{s} )}^{3}$$

$$K = \frac{n ( n + 1 )}{( n - 1 ) ( n - 2 ) ( n - 3 )} \sum {( \frac{{y}_{ij} - \overline{{y}_{i}}}{s} )}^{4} - \frac{3 {( n - 1 )}^{2}}{( n - 2 ) ( n - 3 )}$$

in the equation, n is the number of samples, yᵢ is the i^{th} observation variable, y̅ᵢ̅ is the mean value of the sample data set of the observation variable yᵢ, yᵢⱼ is j^{th} sample data in the sample data set of the observation variable yᵢ, and s is a variance of the sample data set of the observation variable yᵢ;
when an absolute value of the SK is less than 3 and an absolute value of the K is less than 8, it means that the index vector is assumed to conform to a normal distribution;

The processed sample data are imported into the theoretical model, and a covariance matrix is derived from the theoretical model to form a fitting function of a sample covariance matrix and a population covariance matrix, and parameter estimates under the condition of a minimum value of the fitting function are calculated;

assuming that θ is a vector composed of all unknown parameters Λ, B, Γ, Φ, Ψ and Θ in the model, Φ is a covariance matrix of the latent variables ξ, and Ψ is a covariance matrix of a residual vector ζ, Θ is a covariance matrix of a residual vector ε; \hat{θ} is an estimate of θ; the population covariance matrix derived from the theoretical model is Σ(θ), a resulting covariance matrix is expressed as S after the parameters \hat{θ} are estimated according to the samples, and then a real covariance matrix of the index vectors Y₁, Y₂, . . . Yᵢ in a population is:

$$\sum = [ \begin{matrix}var ( {Y}_{1} ) & & & & \\ cov ( {Y}_{2} , {Y}_{1} ) & var ( {Y}_{2} ) & & & \\ ⋮ & ⋮ & ⋱ & & \\ cov ( {Y}_{i - 1} , {Y}_{1} ) & cov ( {Y}_{i - 1} , {Y}_{2} ) & … & var ( {Y}_{i - 1} ) & \\ cov ( {Y}_{i} , {Y}_{1} ) & cov ( {Y}_{i} , {Y}_{2} ) & … & cov ( {Y}_{i} , {Y}_{i - 1} ) & var ( {Y}_{i} )\end{matrix} ]$$

a covariance matrix among the endogenous observation variables Y is:

$$S = [ \begin{matrix}cov ( {Y}_{1} , {Y}_{1} ) & & & & \\ cov ( {Y}_{2} , {Y}_{1} ) & cov ( {Y}_{2} , {Y}_{1} ) & & & \\ ⋮ & ⋮ & ⋱ & & \\ cov ( {Y}_{i - 1} , {Y}_{1} ) & cov ( {Y}_{i - 1} , {Y}_{2} ) & … & cov ( {Y}_{i - 1} , {Y}_{8} ) & \\ cov ( {Y}_{i} , {Y}_{1} ) & cov ( {Y}_{i} , {Y}_{2} ) & … & cov ( {Y}_{i} , {Y}_{i - 1} ) & var ( {Y}_{i} , {Y}_{i} )\end{matrix} ]$$

then a difference function between S and Σ(θ) is:

F(S, Σ(θ))

in the equation, F is a value of a distance between the sample covariance matrix S and the population covariance matrix Σ(θ) of the theoretical model;

when the index vectors are assumed to follow a multidimensional normal distribution, a function is fitted using the maximum likelihood estimation method:

$${F ( S , \sum ( θ ) )}_{ML} = tr ( {SE}^{- 1} ( θ ) ) + log \vert \sum ( θ ) \vert - log \vert S \vert - p$$

in the equation, tr(A) is a trace of the matrix A, namely, a sum of the diagonal elements of the matrix A; log|A| is a determinant logarithm of the matrix A; and p is the number of measured variables;

when the index vectors are assumed not to follow a multidimensional normal distribution, a function is fitted using the generalized least square method:

$${F ( S , \sum ( θ ) )}_{GLS} = \frac{1}{2} tr \{ {[ ( S - \sum ( θ ) ) {W}^{- 1} ]}^{2} \}$$

in the equation, W⁻¹ is a weighted matrix of a residual matrix and is a positive-definite matrix; when W⁻¹=S⁻¹, then:

$${F ( S , \sum ( θ ) )}_{GLS} = \frac{1}{2} tr \{ {[ ( I - \sum ( θ ) ) {S}^{- 1} ]}^{2} \}$$

The seven fitting indexes of χ²/df, GFI, RMSEA, NFI, CFI, PGFI and PNFI are calculated and taken as the indexes for determining the fit between the theoretical model and the measured data, specifically:

### (1) Ratio of Chi-Square to Degrees of Freedom (λ²/Df):

$${χ}^{2} / df = \frac{( n - 1 ) {F}_{min}}{\frac{1}{2} ( p + q ) ( p + q + 1 ) - t}$$

in the equation, n is the number of samples, Fₘᵢₙ is an aggregated adaptation function value after model estimation, p is the number of exogenous observation variables, q is the number of endogenous observation variables, and t is the number of free parameters to be estimated in the model;

### (2) Root Mean Square Error of Approximation (RMSEA):

$$RMSEA = \sqrt{max ( \frac{{F}_{min}}{d f} - \frac{1}{n - 1} , 0 )}$$

in the equation, n is the number of samples, Fₘᵢₙ is an aggregated adaptation function value after model estimation, and df is a degree of freedom of the model;

### (3) Goodness of Fit Index (GFI):

$$G F I = 1 - \frac{t {r [ {Σ}^{- 1} ( S - Σ ) ]}^{2}}{t {r ( {Σ}^{- 1} S )}^{2}}$$

in the equation, tr(A) is a trace of the matrix A, S is an observation matrix of the sample data, and Σ is the population covariance matrix of the model;

### (4) Normed Fit Index (NFI):

$$NFI = \frac{{χ}_{null}^{2} - {χ}_{t e s t}^{2}}{{χ}_{null}^{2}}$$

in the equation, χₙᵤₗₗ² represents a chi-square value obtained from a fitting virtual model, and χₜₑₛₜ² represents a chi-square value obtained from the theoretical model;

### (5) Comparative Fit Index (CFI):

$$CFI = 1 - \frac{max [ {χ}_{t e s t}^{2} - d {f}_{t e s t} ) , 0 ]}{max [ {χ}_{t e s t}^{2} - d {f}_{t e s t} ) , ( {χ}_{null}^{2} - d {f}_{null} ) , 0 ]}$$

in the equation, χₙᵤₗₗ² represents the chi-square value obtained from the fitting virtual model, χₜₑₛₜ² represents the chi-square value obtained from the theoretical model, dfₜₑₛₜ represents a degree of freedom of the fitting virtual model, and dfₙᵤₗₗ represents a degree of freedom of the theoretical model;

### (6) Parsimony Normed Fit Index (PNFI)

$$PNFI = \frac{d {f}_{t e s t}}{d {f}_{null}} ( 1 - \frac{{χ}_{t e s t}^{2}}{{χ}_{null}^{2}} )$$

in the equation, χₙᵤₗₗ² represents the chi-square value obtained from the fitting virtual model, χₜₑₛₜ² represents the chi-square value obtained from the theoretical model, dfₜₑₛₜ represents a degree of freedom of the fitting virtual model, and dfₙᵤₗₗ represents a degree of freedom of the theoretical model;

### (7) Parsimony Goodness of Fit Index (PGFI)

$$PGFI = \frac{d {f}_{t e s {t}^{′}}}{\frac{1}{2} p ( p + 1 )} \times G F I$$

in the equation, dfₜₑₛₜ′ represents a degree of freedom of the theoretical model, p is the number of exogenous observation variables, and GFI is the goodness of fit index.

Further, a calculation process of the weights includes:

establishing an weight set W of the observation variables, normalizing the calculated standardized path coefficient γⱼ among the latent variables and the standardized path coefficient λᵢⱼ between the latent variables and the observation variables, and calculating the weight of each observation variable:

$${ω}_{ij} = {λ}_{ij} \times {γ}_{i}$$

calculating dynamic threshold intervals and a critical value according to the distribution intervals of the sample data of each observation element, and defining the data set into five interval levels D1, D2, D3, D4, D5 according to the probability of data distribution, and assigning values from low to high;

$${p}_{ij} = \{ \begin{matrix}1 , {x}_{ij} ∈ [ {x}_{min} , {x}_{10 \%} ) ⋃ ( {x}_{90 \%} , {x}_{max} ] \\ 2 , {x}_{ij} ∈ [ {x}_{10 \%} , {x}_{20 \%} ) ⋃ ( {x}_{80 \%} , {x}_{90 \%} ] \\ 3 , {x}_{ij} ∈ [ {x}_{20 \%} , {x}_{30 \%} ) ⋃ ( {x}_{70 \%} , {x}_{80 \%} ] \\ 4 , {x}_{ij} ∈ [ {x}_{30 \%} , {x}_{40 \%} ) ⋃ ( {x}_{60 \%} , {x}_{70 \%} ] \\ 5 , {x}_{ij} ∈ [ {x}_{40 \%} , {x}_{60 \%} ]\end{matrix}$$

in the equation, xᵢⱼ represents actual measurement data of the j^{th} measurement variables of the i^{th} latent variables, x̅ is a mean value of the sample data set, s is a standard deviation of the sample data set, and pᵢⱼ is a grade of quality values of the j^{th} measurement variables of the i^{th} latent variables.

Further, the number of free parameters to be estimated in the model includes regression coefficient, variance, and covariance.

Further, among weights of all observation variables, Σγᵢ=1 and Σλᵢⱼ=1.

Further, an apparatus includes:
one or more processors;
a memory configured to store one or more programs; and
when the one or more programs are executed by the one or more processors, the one or more processors implement the method for measuring the quality of the built environment described above.

A storage medium containing computer-executable instructions, the computer-executable instructions are used to implement the method for measuring the quality of the built environment described above when such instructions are executed by a computer processor.

The present disclosure has the beneficial effects:

1. Aiming at shortcomings of low reliability and low precision of quantitative description or qualitative analysis of sub-item element features of a few typical cases, the present disclosure collects a large number of typical cases to form a built environment sample library, extracts sample vector spatial data to form a multidimensional data set, and improves the accuracy of assessment results.

2. Aiming at the problem of poor accuracy of assessment results due to unreasonable interval division of quality assessment values in the prior art, data parameter intervals are set and values are assigned thereto by analyzing the dynamic distribution law of real-time data, and data are effectively divided into dynamic intervals, thereby achieving an overall, scientific and accurate analysis of attributes of the built environment, and making the assessment results more scientific and reasonable and conforming to the objective reality.

3. Aiming at a lack of a comprehensive influence mechanism for analyzing elements and the quality of the built environment, the present disclosure, by using a reasonable and rigorous algorithm, makes clear mutual influence relationship between components of the built environment and the environmental quality, effectively verifies and identifies a key factor and index system suitable for the quality assessment of specific types of the built environment, thereby solving empirical and probabilistic problems of establishing an assessment system through empirical judgment and forming weight results through subjective scoring in the past. Moreover, the present disclosure assesses the environmental quality through the reasonable and rigorous algorithm, and achieves efficient calculation and objective weighting of standard vectors of various observation elements, thereby filling the gap in the research on reasonableness of assessment indexes and accuracy of assessment results in the field of environmental quality assessment of the built environment.

4. Aiming at the defect that only data before and after the transformation of sub-elements of a single dimension of a single sample are compared to determine whether it meets the expectation in the quality assessment process, the present disclosure makes a quantitative measurement of the quality of sub-elements and comprehensive quality by integrating the law of comprehensive data composition and the action mechanism of elements, such that the quality predication and comparison of multiple design schemes can be performed in the early stage of the reconstruction of the built environment, thereby reducing the costs of optimization and assessment of the built projects, improving the accuracy of quality analysis results and the decision-making efficiency of design practice.

### BRIEF DESCRIPTION OF THE DRAWINGS

In order to more clearly illustrate technical solutions in the examples of the present disclosure or in the prior art, a brief introduction to the accompanying drawings required for the description of the examples or the prior art will be provided below. Apparently, those ordinary skilled in the art would also be able to derive other drawings from these drawings without making creative efforts.

FIG. 1 is a flow diagram of the present disclosure.

### DESCRIPTION OF THE EMBODIMENTS

The technical solutions in embodiments of the present disclosure will be clearly and completely described below with reference to the accompanying drawings in the embodiments of the present disclosure. Apparently, the embodiments described are merely some rather than all of the embodiments of the present disclosure. All other embodiments obtained by those of ordinary skill in the art on the basis of the embodiments of the present disclosure without creative efforts shall fall within the protection scope of the present disclosure.

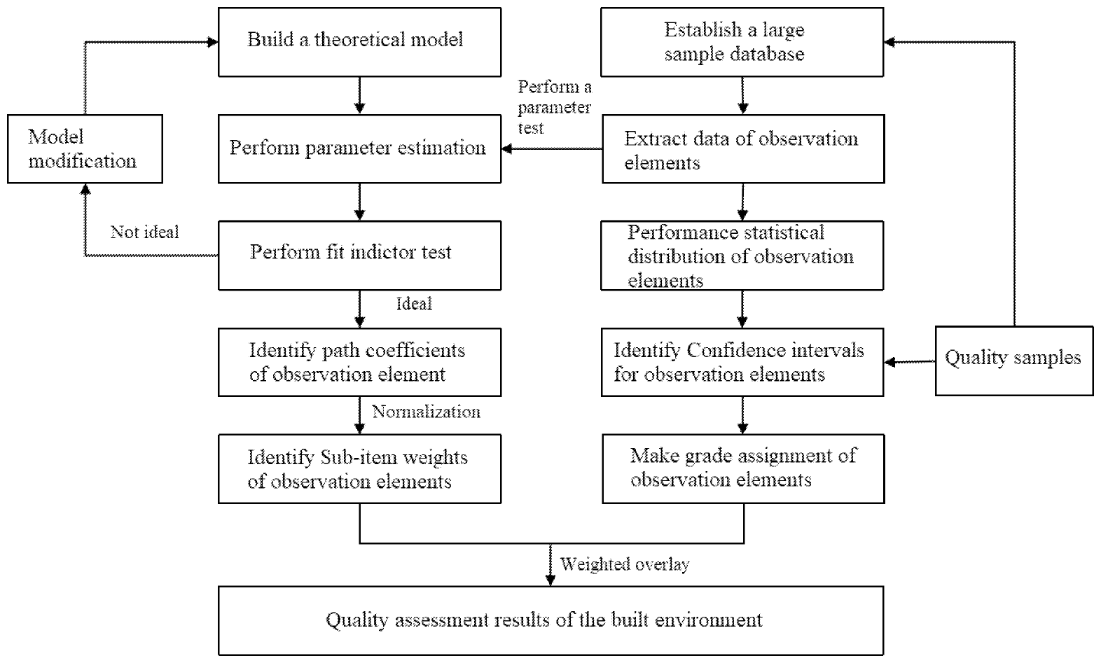

As shown in FIG. 1, a method for measuring the quality of a built environment, including the following steps:
identifying key influencing factors determining the environmental quality, and establishing an index system of environmental quality influencing factors, where the key influencing factors include non-observation elements and observation elements;
analyzing the relationship between the environmental quality and the key influencing factors to form a theoretical model;
acquiring observation elements to form a large sample database;
calculating path coefficients of each key influencing factor of environmental quality according to the distribution of sample data in the large sample database, and converting the path coefficients into weights;
dividing distribution intervals of all observation elements dynamically according to the distribution of sample data, and defining quality assignments of all observation elements; and
performing a comprehensive quality measurement of samples in combination with the weights and the quality assignments.

Taking a spatial environment of a street block as an example, the present example extracts factors and observation elements affecting its environmental quality, and establishes an index system of observation elements and non-observation elements that constitute the street block environment, as shown in Table 1.

TABLE 1
Street Block Environmental Quality Influencing Factors

| Non-observation elements | | | | Observation elements | |
|---|---|---|---|---|---|
| ξ₁ | Street block | η₁ | Network | y₁ | Integration of scenic spots |
| | environmental | | structure | y₂ | Node connectivity |
| | quality | | | y₃ | Recreational travel |
| | | | | y₄ | Spatial topological depth |
| | | η₂ | Spatial layout | y₅ | Road network density |
| | | | | y₆ | Greenery coverage |
| | | η₃ | Spatial scale | y₇ | Length of street block |
| | | η₄ | Spatial density | y₈ | Street spacing |
| | | | | y₉ | Landscape spatial density |

It should be further stated that the present example puts forward the following theoretical assumptions:

Theoretical assumption H1: there is a positive correlation between the street network structure and the street block environmental quality.

Theoretical assumption H2: there is a negative correlation between the spatial layout and the street block environmental quality

Theoretical assumption H3: there is a positive correlation between the street block scale and the street block environmental quality.

Theoretical assumption H4: there is a positive correlation between the spatial density and the street block environmental quality.

Theoretical assumption H5: there is a positive correlation between the street network structure and the spatial layout.

The street block is taken as a sample according to the theoretical assumption provided in the above steps, non-observation elements are taken as the endogenous latent variables, the quality is taken as the exogenous latent variable, and various observation elements are taken as observation variables to form a correlation model of factors affecting the quality influencing factors of the built environment. Regression equations among latent variables, as well as between latent variables and observation variables are established according to the theoretical model:

$$Assuming : Y = [ \begin{matrix}{y}_{1} \\ {y}_{2} \\ {y}_{3} \\ {y}_{4} \\ {y}_{5} \\ {y}_{6} \\ {y}_{7} \\ {y}_{8} \\ {y}_{9}\end{matrix} ] , {Λ}_{y} = [ \begin{matrix}{λ}_{11} & 0 & 0 & 0 \\ {λ}_{21} & 0 & 0 & 0 \\ {λ}_{31} & 0 & 0 & 0 \\ {λ}_{41} & 0 & 0 & 0 \\ 0 & {λ}_{52} & 0 & 0 \\ 0 & {λ}_{62} & 0 & 0 \\ 0 & 0 & {λ}_{73} & 0 \\ 0 & 0 & {λ}_{83} & 0 \\ 0 & 0 & 0 & {λ}_{94}\end{matrix} ] , η = [ \begin{matrix}{η}_{1} \\ {η}_{2} \\ {η}_{3} \\ {η}_{4}\end{matrix} ] , ε = [ \begin{matrix}{ε}_{1} \\ {ε}_{2} \\ {ε}_{3} \\ {ε}_{4} \\ {ε}_{5} \\ {ε}_{6} \\ {ε}_{7} \\ {ε}_{8} \\ {ε}_{9}\end{matrix} ]$$

a matrix equation between latent variables and observation variables is:

$$[ \begin{matrix}{y}_{1} \\ {y}_{2} \\ {y}_{3} \\ {y}_{4} \\ {y}_{5} \\ {y}_{6} \\ {y}_{7} \\ {y}_{8} \\ {y}_{9}\end{matrix} ] = [ \begin{matrix}{λ}_{11} & 0 & 0 & 0 \\ {λ}_{21} & 0 & 0 & 0 \\ {λ}_{31} & 0 & 0 & 0 \\ {λ}_{41} & 0 & 0 & 0 \\ 0 & {λ}_{52} & 0 & 0 \\ 0 & {λ}_{62} & 0 & 0 \\ 0 & 0 & {λ}_{73} & 0 \\ 0 & 0 & {λ}_{83} & 0 \\ 0 & 0 & 0 & {λ}_{94}\end{matrix} ] \times [ \begin{matrix}{η}_{1} \\ {η}_{2} \\ {η}_{3} \\ {η}_{4}\end{matrix} ] + [ \begin{matrix}{ε}_{1} \\ {ε}_{2} \\ {ε}_{3} \\ {ε}_{4} \\ {ε}_{5} \\ {ε}_{6} \\ {ε}_{7} \\ {ε}_{8} \\ {ε}_{9}\end{matrix} ]$$

$$namely : Y = {Λ}_{y} η + ε$$

$$assuming : η = [ \begin{matrix}{η}_{1} \\ {η}_{2} \\ {η}_{3} \\ {η}_{4}\end{matrix} ] , B = [ \begin{matrix}0 & β & 0 & 0 \\ 0 & 0 & 0 & 0 \\ 0 & 0 & 0 & 0 \\ 0 & 0 & 0 & 0\end{matrix} ] , Γ = [ \begin{matrix}{r}_{1} \\ {r}_{2} \\ {r}_{3} \\ {r}_{4}\end{matrix} ] , ξ = {ξ}_{1} , ζ = [ \begin{matrix}{ζ}_{1} \\ {ζ}_{2} \\ {ζ}_{3} \\ {ζ}_{4}\end{matrix} ]$$

a matrix equation among the latent variables is:

$$[ \begin{matrix}{η}_{1} \\ {η}_{2} \\ {η}_{3} \\ {η}_{4}\end{matrix} ] = [ \begin{matrix}0 & β & 0 & 0 \\ 0 & 0 & 0 & 0 \\ 0 & 0 & 0 & 0 \\ 0 & 0 & 0 & 0\end{matrix} ] \times [ \begin{matrix}{η}_{1} \\ {η}_{2} \\ {η}_{3} \\ {η}_{4}\end{matrix} ] + [ \begin{matrix}{r}_{1} \\ {r}_{2} \\ {r}_{3} \\ {r}_{4}\end{matrix} ] \times {ξ}_{1} + [ \begin{matrix}{ζ}_{1} \\ {ζ}_{2} \\ {ζ}_{3} \\ {ζ}_{4}\end{matrix} ]$$

$$namely : η = B η + Γξ + ζ$$

in the equation, yᵢ is an endogenous observation variable;
Y is a 9×1-dimensional vector composed of 9 endogenous observation variables;
Λ_{y} is a 9×4-dimensional loading matrix of Y on η, reflecting the relationship between the endogenous observation variable y and the endogenous latent variable η;
ε is a 9×1-dimensional vector composed of 9 measurement errors, and is an error item of the observation variables Y;
ξ is a 1×1-dimensional vector composed of 1 exogenous latent variable;
η is a 4×1-dimensional vector composed of 4 endogenous latent variables;
B is a 4×4-dimensional coefficient matrix, which represents the interrelationship among endogenous latent variables η;
Γ is a 4×1-dimensional coefficient matrix, which represents the influence of exogenous latent variable ξ on the endogenous latent variables η; and
ζ is a 1×1-dimensional vector composed of 4 interpretation errors.

An establishment process of the large sample database is as follows:
selecting samples based on the clarity, completeness and availability of vector data of street block entities and the accuracy of data capable of meeting the requirements for subsequent data analysis, and selecting more than 100 typical cases to form a large sample case base;
collecting geographical surveying maps and satellite images of the area where the samples are located, and acquiring environmental vector data of the observation elements in combination with the features of the environment; and
it should be further stated that, during specific implementation process, the meaning of the observation elements of the present example are shown in Table 2.

TABLE 2
Street Block Environmental Quality Influencing Elements

| | Observation | | |
|---|---|---|---|
| | elements | Content and meaning | Calculation formula |
| y₁ | Integration of scenic spots | To measure the degree of closeness of a certain road in the sample area, and describing the ″centrality″ of the road and the use efficiency of environment. | $\begin{matrix}{MD}_{i} = \frac{1}{n - 1} {\sum }_{j = 1}^{n} {d}_{ij} \\ {RA}_{i} = \frac{2 ( {MD}_{i} - 1 )}{n - 2} \\ {y}_{2} = \frac{{\sum }_{i}^{n} {RA}_{i}}{n}\end{matrix}$ |
| y₂ | Node connectivity | To measure the number of connections between a certain street space and other adjacent streets in the range of sample, the higher the connection value is, the stronger the correlation and interaction between the environment and the surrounding environment becomes. | $\begin{matrix}{C}_{3} = \sum {R}_{ij} \\ {y}_{4} = \frac{{\sum }_{i}^{n} {C}_{i}}{n}\end{matrix}$ |
| y₃ | Recreational travel | To measure the quantitative relationship among such factors as spatial connection relationship, angle change relationship and spatial conversion times. | $\begin{matrix}{NACH}_{i} = \frac{log ( {ACH\_r}_{i} + 1 )}{log ( {ATD\_r}_{i} + 3 )} \\ {y}_{1} = \frac{{\sum }_{i}^{n} {NACH}_{i}}{n}\end{matrix}$ |
| y₄ | Spatial topological depth | To measure the accessibility of each road location in the sample area to other road spaces. | $\begin{matrix}{Z}_{i} = {\sum }_{j = 1}^{n} {d}_{ij} \\ {y}_{3} = \frac{{\sum }_{i}^{n} {Z}_{i}}{n}\end{matrix}$ |
| y₅ | Road network density | To describe the accessibility and permeability of traffic in the street block space, and the dense road network promotes the degree of connectivity between roads and diversified path selection. | ${y}_{5} = \frac{{L}_{area}}{{S}_{area}}$ |
| y₆ | Greenery coverage | To measure the proportion of shade provided by vegetation in the environment of the street block. | ${y}_{8} = \frac{{S}_{cover}}{{S}_{area}}$ |
| y₇ | Length of | To describe the walking distance of main streets in | y₇ = max L_{N} |
| | street block | the street block. | |
| y₈ | Street spacing | To measure vertical distances between boundary buildings or structures on either side of the street. | ${y}_{6} = \frac{{\sum }_{i}^{N} {DI}_{i}}{N}$ |
| y₉ | Landscape spatial density | To measure compact relationships between physical structures (buildings, structures and the like) and absolute spaces in the street block space. | ${y}_{9} = \frac{{V}_{structure}}{{V}_{area}}$ |

To standardize the original data set and giving reverse assignment of negative correlated elements;

$$Positive indicators : {y}_{ij} = \frac{{y}_{i j} - min \{ {y}_{i 1} , {y}_{i 2} , … {y}_{in} \}}{max \{ {y}_{i 1} , {y}_{i 2} , … {y}_{i n} \} - min \{ {y}_{i 1} , {y}_{i 2} , … {y}_{i n} \}}$$

$$Negative indicators : {y}_{ij} = \frac{max \{ {y}_{i 1} , {y}_{i 2} , … {y}_{i n} \} - {y}_{i j}}{max \{ {y}_{i 1} , {y}_{i 2} , {y}_{i n} \} - \{ {y}_{i 1} , {y}_{i 2} , … {y}_{i n} \}}$$

in the equation, yᵢ is the i^{th} endogenous observation variable, yᵢⱼ is the j^{th} sample data in the sample data set of the observation variable yᵢ, {yᵢ₁, yᵢ₂, . . . yᵢₙ} is the sample data set of the observation variable y₁, and n is the number of samples.

A normality test on index vectors is performed, and a skewness coefficient (SK) and a kurtosis coefficient (K) of each index vector is calculated;

$$S K = \frac{n}{( n - 1 ) ( n - 2 )} \sum {( \frac{{y}_{i j} - \overline{{y}_{i}}}{s} )}^{3}$$

$$K = \frac{n ( n + 1 )}{( n - 1 ) ( n - 2 ) ( n - 3 )} \sum {( \frac{{y}_{i j} - \overline{{y}_{i}}}{s} )}^{4} - \frac{3 {( n - 1 )}^{2}}{( n - 2 ) ( n - 3 )}$$

in the equation, n is the number of samples, yᵢ is the i^{th} observation variable, y̅ᵢ̅ is the mean value of the sample data set of the observation variable yᵢ, yᵢⱼ is j^{th} sample data in the sample data set of the observation variable yᵢ, and s is a variance of the sample data set of the observation variable yᵢ;
when an absolute value of the SK is less than 3 and an absolute value of the K is less than 8, it means that the index vector is assumed to conform to a normal distribution; and
it should be further stated that, during specific implementation, test results of the skewness coefficient SK and the kurtosis coefficient K in the present example are shown in Table 3, and all the observation variables conform to normal distribution.

TABLE 3
Normality Test Results

| | Landscape | | | Integration | Spatial | | Road | Street | Length |
|---|---|---|---|---|---|---|---|---|---|
| | spatial | Greenery | Recreational | of scenic | topological | Node | network | interface | of street |
| | density | coverage | travel | spots | depth | connectivity | density | width | block |
| Skewness | 0.832 | 0.046 | 2.281 | 0.256 | 2.298 | 1.397 | 0.659 | 0.827 | 0.965 |
| coefficient | | | | | | | | | |
| SK | | | | | | | | | |
| Kurtosis | 1.688 | −1.197 | 4.918 | −0.139 | 5.206 | 2.141 | −0.153 | 1.694 | 0.356 |
| coefficientK | | | | | | | | | |

The processed sample data are imported into the theoretical model, and a covariance matrix is derived from the theoretical model to form a fitting function of a sample covariance matrix and a population covariance matrix, and parameter estimates under the condition of a minimum value of the fitting function are calculated;

assuming that θ is a vector composed of all unknown parameters Λ, B, Γ, Φ, Ψ and Θ in the model, Φ is a covariance matrix of the latent variables ξ, and Ψ is a covariance matrix of a residual vector ξ, Θ is a covariance matrix of a residual vector ε; \hat{θ} is an estimate of θ; the population covariance matrix derived from the theoretical model is Σ(θ), a resulting covariance matrix is expressed as S after the parameters \hat{θ} are estimated according to the samples, and then a real covariance matrix of the index vectors Y₁, Y₂, . . . Yᵢ in a population is:

$$\sum = [ \begin{matrix}var ( {Y}_{1} ) & & & & \\ cov ( {Y}_{2} , {Y}_{1} ) & var ( {Y}_{2} ) & & & \\ ⋮ & ⋮ & ⋱ & & \\ cov ( {Y}_{8} , {Y}_{1} ) & cov ( {Y}_{8} , {Y}_{2} ) & … & var ( {Y}_{8} ) & \\ cov ( {Y}_{9} , {Y}_{1} ) & cov ( {Y}_{9} , {Y}_{2} ) & … & cov ( {Y}_{9} , {Y}_{8} ) & var ( {Y}_{9} )\end{matrix} ]$$

a covariance matrix among the endogenous observation variables Y is:

$$S = [ \begin{matrix}cov ( {Y}_{1} , {Y}_{1} ) & & & & \\ cov ( {Y}_{2} , {Y}_{1} ) & cov ( {Y}_{2} , {Y}_{1} ) & & & \\ ⋮ & ⋮ & ⋱ & & \\ cov ( {Y}_{8} , {Y}_{1} ) & cov ( {Y}_{8} , {Y}_{2} ) & … & cov ( {Y}_{8} , {Y}_{8} ) & \\ cov ( {Y}_{9} , {Y}_{1} ) & cov ( {Y}_{9} , {Y}_{2} ) & … & cov ( {Y}_{9} , {Y}_{8} ) & cov ( {Y}_{9} , {Y}_{9} )\end{matrix} ]$$

then a difference function between S and Σ(θ) is:

F(S, Σ(θ))

in the equation, F is a value of a distance between the sample covariance matrix S and the population covariance matrix Σ(θ) of the model;

when the index vectors are assumed to follow a multidimensional normal distribution, a function is fitted using the maximum likelihood estimation method:

$${F ( S , Σ ( θ ) )}_{ML} = t r ( {SE}^{- 1} ( θ ) ) + log \vert Σ ( θ ) \vert - log \vert S \vert - p$$

in the equation, tr(A) is a trace of the matrix A, namely, a sum of the diagonal elements of the matrix A; log|A| is a determinant logarithm of the matrix A; and p is the number of measured variables;

when the index vectors are assumed not to follow a multidimensional normal distribution, a function is fitted using the generalized least square method:

$${F ( S , Σ ( θ ) )}_{G L S} = \frac{1}{2} t r \{ {[ ( S - Σ ( θ ) ) {W}^{- 1} ]}^{2} \}$$

in the equation, W⁻¹ is a weighted matrix of a residual matrix and is a positive-definite matrix; when W⁻¹=S⁻¹, then:

$${F ( S , Σ ( θ ) )}_{G L S} = \frac{1}{2} t r \{ {[ ( I - Σ ( θ ) ) {S}^{- 1} ]}^{2} \}$$

The seven fitting indexes of χ²/df, GFI, RMSEA, NFI, CFI, PGFI and PNFI are calculated and taken as the indexes for determining the fit between the theoretical model and the measured data, specifically:

(1) Ratio of Chi-Square to Degrees of Freedom (χ²/df):

$${χ}^{2} / df = \frac{( n - 1 ) {F}_{min}}{\frac{1}{2} ( p + q ) ( p + q + 1 ) - t}$$

in the equation, n is the number of samples, Fₘᵢₙ is an aggregated adaptation function value after model estimation, p is the number of exogenous observation variables, q is the number of endogenous observation variables, and t is the number of free parameters to be estimated in the model, including regression coefficient, variance, and covariance.

### (2) Root Mean Square Error of Approximation (RMSEA):

$$R M S E A = \sqrt{max ( \frac{{F}_{min}}{df} - \frac{1}{n - 1} , 0 )}$$

in the equation, n is the number of samples, Fₘᵢₙ is an aggregated adaptation function value after model estimation, and df is a degree of freedom of the model;

### (3) Goodness of Fit Index (GFI):

$$G F I = 1 - \frac{{tr [ {\sum }^{- 1} ( S - \sum ) ]}^{2}}{{tr ( {\sum }^{- 1} S )}^{2}}$$

in the equation, tr(A) is a trace of the matrix A, S is an observation matrix of the sample data, and Σ is the population covariance matrix of the model;

### (4) Normed Fit Index (NFI):

$$N F I = \frac{{χ}_{null}^{2} - {χ}_{t e s t}^{2}}{{χ}_{null}^{2}}$$

in the equation, χₙᵤₗₗ² represents a chi-square value obtained from a fitting virtual model, and χₜₑₛₜ² represents a chi-square value obtained from the theoretical model;

### (5) Comparative Fit Index (CFI):

$$C F I = 1 - \frac{max [ {χ}_{t e s t}^{2} - {df}_{test} ) , 0 ]}{max [ {χ}_{t e s t}^{2} - {df}_{t e s t} ) , ( {χ}_{null}^{2} - {df}_{null} ) , 0 ]}$$

in the equation, χₙᵤₗₗ² represents the chi-square value obtained from the fitting virtual model, χₜₑₛₜ² represents the chi-square value obtained from the theoretical model, dfₜₑₛₜ and dfₙᵤₗₗ represent degrees of freedom of the fitting virtual model and the theoretical model;

### (6) Parsimony Normed Fit Index (PNFI)PNFI

$$P N F I = \frac{{df}_{t e s t}}{{df}_{null}} ( 1 - \frac{{χ}_{t e s t}^{2}}{{χ}_{null}^{2}} )$$

in the equation, χₙᵤₗₗ² represents the chi-square value obtained from the fitting virtual model, χₜₑₛₜ² represents the chi-square value obtained from the theoretical model, dfₜₑₛₜ and dfₙᵤₗₗ represent degrees of freedom of the fitting virtual model and the theoretical model;

### (7) Parsimony Goodness of Fit Index (PNFI)PGFI

$$P G F I = \frac{{df}_{test}}{\frac{1}{2} p ( p + 1 )} \times G F I$$

in the equation, dfₜₑₛₜ represents a degree of freedom of the theoretical model, p is the number of exogenous observation variables, and GFI is the goodness of fit index.

It should be further stated that, during specific implementation, test standards for the overall model fitness and test results of the present example are shown in Table 4.

TABLE 4
Fit Indicator Test Standards

| | Fit | Fit | Fit | Result |
|---|---|---|---|---|
| Model fit indicator | index | standards | result | interpretation |
| Absolute fit index | χ²/df | 1 < χ²/df < 3 | 2.290 | Ideal |
| | RMSEA | <0.10 | 0.087 | Relatively ideal |
| Relative fit index | GFI | >0.90 | 0.904 | Ideal |
| | NFI | >0.90 | 0.912 | Ideal |
| | CFI | >0.90 | 0.917 | Ideal |
| Parsimony fit | PNFI | >0.50 | 0.504 | Ideal |
| index | PGFI | >0.50 | 0.538 | Ideal |

A calculation process of the weights includes:

establishing an weight set W of the observation variables, normalizing the calculated standardized path coefficient γᵢ among the latent variables and the standardized path coefficient λᵢⱼ between the latent variables and the observation variables, and calculating the weight of each observation variable:

$${ω}_{i j} = {λ}_{i j} \times {γ}_{i}$$

in the equation,

Σγᵢ=1

Σλᵢⱼ=1

Normalized processing results of path coefficients of non-observation elements and observation elements and their comprehensive weight values in the present example are shown in Table 5.

TABLE 5
Normalized Processing Results of the Present Example

| Non- | | Normalized | | | Normalized | |
|---|---|---|---|---|---|---|
| observation | Path | path | Observation | Factor | factor | Comprehensive |
| elements | coefficient | coefficient | elements | loading | loading | weight |
| Network | 0.64 | 0.45 | Integration of | 0.13 | 0.05 | 0.02 |
| structure | | | scenic spots | | | |
| | | | Node connectivity | 0.59 | 0.22 | 0.10 |
| | | | Recreational travel | 0.96 | 0.36 | 0.16 |
| | | | Spatial topological | 0.96 | 0.36 | 0.16 |
| | | | depth | | | |
| Spatial | −0.20 | −0.14 | Road network | 0.55 | 0.65 | −0.09 |
| layout | | | density | | | |
| | | | Greenery coverage | 0.30 | 0.35 | −0.05 |
| Scale of | 0.66 | 0.46 | Length of street | 0.62 | 0.70 | 0.33 |
| street block | | | block | | | |
| | | | Street width | 0.26 | 0.30 | 0.14 |
| Spatial | 0.33 | 0.23 | Landscape spatial | 1.00 | 1.00 | 0.23 |
| density | | | density | | | |

calculating dynamic threshold intervals and a critical value according to the distribution intervals of the sample data of each observation element, and defining the data set into five interval levels D1, D2, D3, D4, D5 according to the probability of data distribution, and assigning values from low to high.

$${p}_{ij} = \{ \begin{matrix}1 , {x}_{ij} ∈ [ {x}_{min} , {x}_{10 \%} ) ⋃ ( {x}_{90 \%} , {x}_{max} ] \\ 2 , {x}_{ij} ∈ [ {x}_{10 \%} , {x}_{20 \%} ) ⋃ ( {x}_{80 \%} , {x}_{90 \%} ] \\ 3 , {x}_{ij} ∈ [ {x}_{20 \%} , {x}_{30 \%} ) ⋃ ( {x}_{70 \%} , {x}_{80 \%} ] \\ 4 , {x}_{ij} ∈ [ {x}_{30 \%} , {x}_{40 \%} ) ⋃ ( {x}_{60 \%} , {x}_{70 \%} ] \\ 5 , {x}_{ij} ∈ [ {x}_{40 \%} , {x}_{60 \%} ]\end{matrix}$$

in the equation, xᵢⱼ represents actual measurement data of the j^{th} measurement variables of the i^{th} latent variables, x̅ is a mean value of the sample data set, s is a standard deviation of the sample data set, and pᵢⱼ is a grade of quality values of the j^{th} measurement variables of the i^{th} latent variables.

Interval critical values of each observation element in the present example based on the sample data set are shown in Table 6.

TABLE 6
Observation Element Grade Interval of the Present Example

| Observation | | | | | |
|---|---|---|---|---|---|
| elements | D1 | D2 | D3 | D4 | D5 |
| Integration of | [0.89, 1.25) ∪ | [1.25, 1.42) ∪ | [1.42, 1.52) ∪ | [1.52, 1.74) ∪ | [1.74, 1.99] |
| scenic spots | (2.39, 3.09] | (2.28, 2.39] | (2.10, 2.28] | (1.99, 2.10] | |
| Node | [2.67, 3.66) ∪ | [3.66, 4.34) ∪ | [4.34, 4.81) ∪ | [4.81, 5.07) ∪ | [5.07, 6.21] |
| connectivity | (8.99, 15.29] | (8.29, 8,99] | (7.37, 8.29] | (6.21, 7.37] | |
| Recreational | [7.23, 29.22) ∪ | [29.22, 52.07) ∪ | [52.07, 101.04) ∪ | [101.04, 121.83) ∪ | [121.83, 227.72] |
| travel | (1259.21, 2769.43] | (465.87, 1259.21] | (377.45, 465.87] | (227.72, 377.45] | |
| Spatial topo | [19.23, 55.51) ∪ | [55,51, 80.87) ∪ | [80.87, 154.91) ∪ | [154.91, 175.75) ∪ | [175.75, 337.85] |
| logical depth | (1626.21, 3641.43] | (685.77, 1626.21] | (518.72, 685.77] | (337.85, 518.72] | |
| Road network | [19.91, 51.46) ∪ | [51.46, 67.45) ∪ | [67.45, 84.15) ∪ | [84.15, 92.47) ∪ | [92.47, 114.84] |
| density | (217.99, 776.10] | (177.16, 217.99] | (126.97, 177.16] | (114.84, 126.97] | |
| Greenery | [0.02, 0.08) ∪ | [0.08, 0.11) ∪ | [0.11, 0.18) ∪ | [0.18, 0.21) ∪ | [0.21, 0.32] |
| coverage | (0.48, 0.58] | (0.42, 0.48] | (0.39, 0.42] | (0.32, 0.39] | |
| Length of | [51.72, 202.00) ∪ | [202.00, 262.11) ∪ | [262.11, 271.53) ∪ | [271.53, 314.33) ∪ | [314.33, 434.31] |
| street block | (802.95, 1040.29] | (598.14, 802.95] | (500.40, 598.14] | (434.31, 500.40] | |
| Street width | [3.06, 7.72) ∪ | [7.72, 8.84) ∪ | [8.84, 9.98) ∪ | [9.98, 11.46) ∪ | [11.46, 12.92] |
| | (15.93, 25.15] | (14.98, 15.93] | (13.30, 14.98] | (12.92, 13.30] | |
| Landscape | [0.17, 0.23) ∪ | [0.23, 0.28) ∪ | [0.28, 0.32) ∪ | [0.32, 0.34) ∪ | [0.34, 0.41] |
| spatial density | (0.55, 0.81] | (0.49, 0.55] | (0.43, 0.49] | (0.41, 0.43] | |

The quality of assessment indexes of the study case is calculated one by one based on the established quality assessment index system. On this basis, the quality of each element is reclassified and assigned according to the data classification intervals of each observation element, conversion is then made to form quality values of dimensionless elements for the final quality measurement, and then the accumulated calculation is achieved. Finally, based on the weight value of each observation element, all index elements are subject to weighted overlay to obtain values of the environmental quality of the case. In the present example, four street block samples are selected for environmental quality measurement, and observation values and environmental quality of samples are shown in Table 7.

TABLE 7
Observation Values and Environmental Quality of Samples of the Present Example

| | Confucius Temple, | | Pingjiang Road, | | Xijindu Ancient | | | |
|---|---|---|---|---|---|---|---|---|
| | Nanjing City, | | Suzhou City, | | Street, Zhenjiang | | Changnongli Lane, | |
| | Jiangsu Province, | | Jiangsu Province, | | City, Jiangsu | | Zhuji City, Zhejiang | |
| | China | | China | | Province, China | | Province, China | |
| | Observation | Reclassi- | Observation | Reclassi- | Observation | Reclassi- | Observation | Reclassi- |
| | value | fication | value | fication | value | fication | value | fication |
| Spatial density | 0.51 | 2 | 0.22 | 1 | 0.30 | 3 | 0.21 | 1 |
| Greenery | 0.18 | 4 | 0.35 | 4 | 0.47 | 2 | 0.39 | 4 |
| coverage | | | | | | | | |
| Recreational | 156.00 | 5 | 464.44 | 3 | 203.16 | 5 | 70.51 | 3 |
| travel | | | | | | | | |
| Integration of | 1.08 | 1 | 2.05 | 4 | 1.63 | 4 | 1.41 | 2 |
| scenic spots | | | | | | | | |
| Topological | 206.00 | 5 | 642.44 | 3 | 285.16 | 5 | 104.51 | 3 |
| depth | | | | | | | | |
| Node | 2.86 | 1 | 7.18 | 4 | 5.88 | 5 | 3.77 | 2 |
| connectivity | | | | | | | | |
| Street width | 12.40 | 5 | 9.03 | 3 | 14.81 | 3 | 14.02 | 3 |
| Length of | 498.60 | 4 | 339.83 | 5 | 839.54 | 1 | 503.10 | 3 |
| street block | | | | | | | | |
| Road network | 30.74 | 1 | 191.76 | 2 | 38.43 | 1 | 50.28 | 1 |
| density | | | | | | | | |

| | | | | |
|---|---|---|---|---|
| Environmental | 3.91 | 3.36 | 3.43 | 2.55 |
| quality | | | | |

What is shown and described above is about basic principles, essential features and advantages of the present disclosure. It should be understood by those skilled in the art that, the present disclosure is not limited by the embodiments described above. The embodiments described above and the descriptions in the description merely illustrate the principles of the present disclosure. Various changes and modifications may be made to the present disclosure without departing from the spirit and scope of the present disclosure. These changes and modifications all fall within the claimed scope of the present disclosure.

1. A method for measuring the quality of a built environment, comprising the following steps:
identifying key influencing factors determining an environmental quality, and establishing an index system of environmental quality influencing factors, wherein the key influencing factors comprise non-observation elements and observation elements;
analyzing a relationship between the environmental quality and the key influencing factors to form a theoretical model;
acquiring the observation elements to form a large sample database;
calculating path coefficients of each of the key influencing factors of the environmental quality according to a distribution of a sample data in the large sample database, and converting the path coefficients into weights;
dividing distribution intervals of all of the observation elements dynamically according to the distribution of the sample data, and defining quality assignments of all of the observation elements; and
performing a comprehensive quality measurement of samples in combination with the weights and the quality assignments.

2. The method for measuring the quality of the built environment according to claim 1, wherein regression equations among latent variables, as well as between the latent variables and observation variables are established according to the theoretical model:
assuming that there are m types of the non-observation elements and i types of the observation elements among the key influencing factors of environmental quality, wherein the observation elements are the elements that can be measured directly in the built environment, and the corresponding data set is the observation variables; the non-observation elements are the elements that cannot be measured directly in the built environment, which need to be reflected indirectly by actual index values, that is, the latent variables, acquired through an observation, therefore, a matrix equation between the latent variables and the observation variables is:
$$Y = {Λ}_{y} η + ε$$
a matrix equation among the latent variables is:
$$η = B η + Γξ + ζ$$
in the equation:
Y is an i×1-dimensional vector composed of i observation variables yᵢ;
η is an m×1-dimensional vector composed of m latent variables;
Λ_{y} is an i×m-dimensional loading matrix of Y on η, reflecting a relationship between the observation variables Y and the latent variables η;
ε is an i×1-dimensional vector composed of i measurement errors, and is an error item of the observation variables Y;
ξ a 1×1-dimensional vector composed of 1 exogenous latent variable;
B is an m×m-dimensional coefficient matrix, which represents an interrelationship among the endogenous latent variables η, and when there is the interrelationship, a dimension influence coefficient will be recorded as β;
Γ is an m×1-dimensional coefficient matrix composed of m influence coefficients γₘ, which represents an influence of the exogenous latent variable ξ on the endogenous latent variables η; and
ζ is an m×1-dimensional vector composed of m interpretation errors, and is an error item of the latent variables η.

3. The method for measuring the quality of the built environment according to claim 1, wherein an establishment process of the large sample database is as follows:
selecting samples based on a clarity, a completeness and an availability of a vector data of built environment entities and an accuracy of data capable of meeting requirements for a subsequent data analysis to form a large sample case base;
collecting geographical surveying maps and satellite images of the area where the samples are located, and acquiring an environmental vector data of the observation elements in combination with the features of the built environment; and
standardizing an original data set and giving a reverse assignment of negative correlated elements
$${y}_{ij} = \frac{{y}_{ij} - min \{ {y}_{{i}_{1}} , {y}_{{i}_{2}} , … {y}_{in} \}}{max \{ {y}_{{i}_{1}} , {y}_{{i}_{2}} , … {y}_{in} \} - min \{ {y}_{{i}_{1}} , {y}_{{i}_{2}} , … {y}_{in} \}}$$
$${y}_{i j} = \frac{max \{ {y}_{{i}_{1}} , {y}_{{i}_{2}} , … {y}_{in} \} - {y}_{ij}}{max \{ {y}_{{i}_{1}} , {y}_{{i}_{2}} , … {y}_{in} \} - min \{ {y}_{{i}_{1}} , {y}_{{i}_{2}} , … {y}_{in} \}}$$
wherein, yᵢ is an i^{th} endogenous observation variable, yᵢⱼ is a j^{th} sample data in a sample data set of the observation variable yᵢ, {yᵢ₁, yᵢ₂, . . . , yᵢₙ} is the sample data set of the observation variable yᵢ, and n is a number of samples.

4. The method for measuring the quality of the built environment according to claim 3, wherein a basis for a selection of the samples is provided by forming the large sample database.

5. The method for measuring the quality of the built environment according to claim 1, wherein a normality test on index vectors is performed, and a skewness coefficient (SK) and a kurtosis coefficient (K) of each of the index vectors is calculated:
$$SK = \frac{n}{( n - 1 ) ( n - 2 )} \sum {( \frac{{y}_{i j} - \overline{{y}_{i}}}{s} )}^{3}$$
$$K = \frac{n ( n + 1 )}{( n - 1 ) ( n - 2 ) ( n - 3 )} \sum {( \frac{{y}_{i j} - \overline{{y}_{i}}}{s} )}^{4} - \frac{3 {( n - 1 )}^{2}}{( n - 2 ) ( n - 3 )}$$
wherein, η is a number of samples, yᵢ is a i^{th} observation variable, y is a mean value of a sample data set of the observation variable yᵢ, yᵢⱼ is a j^{th} sample data in the sample data set of the observation variable yᵢ, and s is a variance of the sample data set of the observation variable yᵢ;
when an absolute value of the SK is less than 3 and an absolute value of the K is less than 8, it means that the index vectors is assumed to conform to a normal distribution;
the processed sample data are imported into the theoretical model, and a covariance matrix is derived from the theoretical model to form a fitting function of a sample covariance matrix and a population covariance matrix, and parameter estimates under a condition of a minimum value of the fitting function are calculated;
assuming that θ is a vector composed of all unknown parameters Λ, B, Γ, Φ, Ψ and Θ in the model, Φ is a covariance matrix of latent variables ξ, and Ψ is a covariance matrix of a residual vector ζ, Θ is a covariance matrix of a residual vector ε; \hat{θ} is an estimate of θ; the population covariance matrix derived from the theoretical model is Σ(θ), a resulting covariance matrix is expressed as S after the parameters \hat{θ} are estimated according to the samples, and then a real covariance matrix of the index vectors Y₁, Y₂, . . . Yᵢ in a population is:
$$\sum = [ \begin{matrix}var ( {Y}_{1} ) & & & & \\ cov ( {Y}_{2} , {Y}_{1} ) & var ( {Y}_{2} ) & & & \\ ⋮ & ⋮ & ⋱ & & \\ cov ( {Y}_{i - 1} , {Y}_{1} ) & cov ( {Y}_{i - 1 ,} {Y}_{2} ) & … & var ( {Y}_{i - 1} ) & \\ cov ( {Y}_{i} , {Y}_{1} ) & cov ( {Y}_{i} , {Y}_{2} ) & … & cov ( {Y}_{i} , {Y}_{i - 1} ) & var ( {Y}_{i} )\end{matrix} ]$$
a covariance matrix among a endogenous observation variables Y is:
$$S = [ \begin{matrix}cov ( {Y}_{1} , {Y}_{1} ) & & & & \\ cov ( {Y}_{2} , {Y}_{1} ) & cov ( {Y}_{2} , {Y}_{1} ) & & & \\ ⋮ & ⋮ & ⋱ & & \\ cov ( {Y}_{i - 1} , {Y}_{1} ) & cov ( {Y}_{i - 1 ,} {Y}_{2} ) & … & cov ( {Y}_{i - 1} , {Y}_{8} ) & \\ cov ( {Y}_{i} , {Y}_{1} ) & cov ( {Y}_{i} , {Y}_{2} ) & … & cov ( {Y}_{i} , {Y}_{i - 1} ) & cov ( {Y}_{i} , {Y}_{i} )\end{matrix} ]$$
then a difference function between S and Σ(θ) is:
F(S,Σ(θ))
wherein F is a value of a distance between the sample covariance matrix S and the population covariance matrix Σ(θ) of the theoretical model;
when the index vectors are assumed to follow a multidimensional normal distribution, a function is fitted using a maximum likelihood estimation method:
$${F ( S , Σ ( θ ) )}_{M L} = t r ( S {E}^{- 1} ( θ ) ) + log \vert Σ ( θ ) \vert - log \vert S \vert - p$$
wherein, tr(A) is a trace of a matrix A, namely, a sum of diagonal elements of the matrix A; log|A| is a determinant logarithm of the matrix A; and p is a number of measured variables;
when the index vectors are assumed not to follow the multidimensional normal distribution, a function is fitted using a generalized least square method:
$${F ( S , Σ ( θ ) )}_{G L S} = \frac{1}{2} t r \{ {[ ( S - Σ ( θ ) ) {W}^{- 1} ]}^{2} \}$$
wherein, W⁻¹ is a weighted matrix of a residual matrix and is a positive-definite matrix; when W⁻¹=S⁻¹, then:
$${F ( S , Σ ( θ ) )}_{G L S} = \frac{1}{2} t r \{ {[ ( I - Σ ( θ ) ) {S}^{- 1} ]}^{2} \}$$
seven fitting indexes of χ²/df, GFI, RMSEA, NFI, CFI, PGFI and PNFI are calculated and taken as the indexes for determining a fit between the theoretical model and the measured data, wherein:
(1) a ratio of chi-square to degrees of freedom (χ²/df):
$${χ}^{2} / df = \frac{( n - 1 ) {F}_{min}}{\frac{1}{2} ( p + q ) ( p + q + 1 ) - t}$$
wherein, n is a number of samples, Fₘᵢₙ is an aggregated adaptation function value after a model estimation, p is a number of exogenous observation variables, q is a number of endogenous observation variables, and t is a number of free parameters to be estimated in the model;
(2) a root mean square error of approximation (RMSEA):
$$RMSEA = \sqrt{max ( \frac{{F}_{min}}{df} - \frac{1}{n - 1} , 0 )}$$
wherein, n is a number of samples, Fₘᵢₙ is an aggregated adaptation function value after the model estimation, and df is a degree of freedom of the model;
(3) a goodness of fit index (GFI):
$$GFI = 1 - \frac{t {r [ {Σ}^{- 1} ( S - Σ ) ]}^{2}}{t {r ( {Σ}^{- 1} S )}^{2}}$$
wherein, tr(A) is a trace of the matrix A, S is an observation matrix of the sample data, and Σ is the population covariance matrix of the model;
(4) a normed fit index (NFI):
$$NFI = \frac{{χ}_{null}^{2} - {χ}_{t e s t}^{2}}{{χ}_{null}^{2}}$$
wherein, χₙᵤₗₗ² represents a chi-square value obtained from a fitting virtual model, and χₜₑₛₜ² represents a chi-square value obtained from the theoretical model;
(5) a comparative fit index (CFI):
$$CFI = 1 - \frac{max [ ( {χ}_{test}^{2} - d {f}_{test} ) , 0 ]}{max [ ( {χ}_{test}^{2} - d {f}_{test} ) , ( {χ}_{null}^{2} - d {f}_{null} ) , 0 ]}$$
wherein, χₙᵤₗₗ² represents the chi-square value obtained from the fitting virtual model, χₜₑₛₜ² represents the chi-square value obtained from the theoretical model, dfₜₑₛₜ represents a degree of freedom of the fitting virtual model, and dfₙᵤₗₗ represents a degree of freedom of the theoretical model;
(6) a parsimony normed fit index (PNFI)
$$PNFI = \frac{d {f}_{test}}{d {f}_{null}} ( 1 - \frac{{χ}_{test}^{2}}{{χ}_{null}^{2}} )$$
wherein, χₙᵤₗₗ² represents the chi-square value obtained from the fitting virtual model, χₜₑₛₜ² represents the chi-square value obtained from the theoretical model, dfₜₑₛₜ represents a degree of freedom of the fitting virtual model, and dfₙᵤₗₗ represents a degree of freedom of the theoretical model;
(7) a parsimony goodness of fit index (PGFI)
$$PGFI = \frac{{df}_{test}^{′}}{\frac{1}{2} p ( p + 1 )} \times GFI$$
wherein, dfₜₑₛₜ′ represents a degree of freedom of the theoretical model, p is a number of exogenous observation variables, and GFI is the goodness of fit index.

6. The method for measuring the quality of the built environment according to claim 1, wherein a calculation process of the weights comprises:
establishing a weight set W of observation variables, normalizing a calculated standardized path coefficient γᵢ among latent variables and a standardized path coefficient λᵢⱼ between the latent variables and the observation variables, and calculating the weight of each of the observation variables:
$${ω}_{i j} = {λ}_{i j} \times {γ}_{i}$$
calculating dynamic threshold intervals and a critical value according to the distribution intervals of the sample data of each of the observation elements, and defining the data set into five interval levels D1, D2, D3, D4, D5 according to a probability of data distribution, and assigning values from low to high;
$${p}_{ij} = \{ \begin{matrix}1 , {x}_{ij} ∈ [ {x}_{min} , {x}_{10 \%} ) ⋃ ( {x}_{90 \%} , {x}_{max} ] \\ 2 , {x}_{ij} ∈ [ {x}_{10 \%} , {x}_{20 \%} ) ⋃ ( {x}_{80 \%} , {x}_{90 \%} ] \\ 3 , {x}_{ij} ∈ [ {x}_{20 \%} , {x}_{30 \%} ) ⋃ ( {x}_{70 \%} , {x}_{80 \%} ] \\ 4 , {x}_{ij} ∈ [ {x}_{30 \%} , {x}_{40 \%} ) ⋃ ( {x}_{60 \%} , {x}_{70 \%} ] \\ 5 , {x}_{ij} ∈ [ {x}_{40 \%} , {x}_{60 \%} ]\end{matrix}$$
wherein, xᵢⱼ represents an actual measurement data of a j^{th} measurement variables of the i^{th} latent variables, x̅ is a mean value of a sample data set, s is a standard deviation of the sample data set, and pᵢⱼ is a grade of quality values of the j^{th} measurement variables of the i^{th} latent variables.

7. The method for measuring the quality of the built environment according to claim 5, wherein the number of free parameters to be estimated in the model comprises a regression coefficient, the variance and a covariance.

8. The method for measuring the quality of the built environment according to claim 6, wherein among the weights of all observation variables Σγᵢ=1 and Σλᵢⱼ=1.

9. An electronic device, comprising:
one or more processors;
a memory configured to store one or more programs; and
when the one or more programs are executed by the one or more processors, the one or more processors implement the method for measuring the quality of the built environment according to claim 1.

10. A storage medium containing computer-executable instructions, wherein the computer-executable instructions are used to execute the method for measuring the quality of the built environment according to claim 1 when executed by a computer processor.
